(19) United States
(12) Patent Application Publication
(10) Pub. No.: US 2014/0167028 A1
(43) Pub. Date: Jun. 19, 2014

(54) AMINOINDOLO[3,2,1-jk]CARBAZOLE COMPOUND AND ORGANIC LIGHT-EMITTING DEVICE INCLUDING THE SAME

(71) Applicants: Takeshi Sekiguchi, Tokyo (JP); Hiroki Ohrui, Kawasaki-shi (JP); Masanori Muratsubaki, Hachioji-shi (JP)

(72) Inventors: Takeshi Sekiguchi, Tokyo (JP); Hiroki Ohrui, Kawasaki-shi (JP); Masanori Muratsubaki, Hachioji-shi (JP)

(73) Assignee: CANON KABUSHIKI KAISHA, Tokyo (JP)

(21) Appl. No.: 14/236,569

(22) PCT Filed: Jul. 10, 2012
(86) PCT No.: PCT/JP2012/068045

§ 371 Date: Jan. 31, 2014

(30) Foreign Application Priority Data
Aug. 1, 2011 (JP) 2011-168335

(51) Int. Cl. H01L 51/00

(52) U.S. Cl. CPC H01L 51/0061
USPC 257/40; 548/419; 345/82

(57) ABSTRACT

The present invention provides a novel aminoindolo[3,2,1-jk]carbazole compound having a good film-forming property and provides an organic light-emitting device including the compound.

Provided is the aminoindolo[3,2,1-jk]carbazole compound represented by Formula [1] according to Claim 1. In Formula [1], l represents an integer of 1 to 3; n and m each independently represent an integer of 0 to 2; and R¹ to R³² represent hydrogen atom, alkyl groups having 1 to 8 carbon atoms or fluorine atoms, wherein the alkyl groups may contain fluorine atoms.

### TECHNICAL FIELD

The present invention relates to an aminoindolo[3,2,1-jk]carbazole compound and an organic light-emitting device including the compound.

### BACKGROUND ART

An organic light-emitting device includes an anode, a cathode, and an organic compound layer disposed between the electrodes. In the organic light-emitting device, holes and electrons injected from the electrodes are recombined in the organic compound layer to generate excitons, and the excitons emit light when they return to their ground state. Recent considerable progress in organic light-emitting devices allows a reduction in driving voltage, diversification in emission wavelength, rapid responsiveness, and reductions in size and weight of light-emitting devices.

PTL 1 discloses SH-01 represented by the following formula as an aromatic amine compound that can be used in, for example, a hole-transporting layer of an organic light-emitting device.

PTL 2 describes FH-01 represented by the following formula as a compound for an organic light-emitting device.

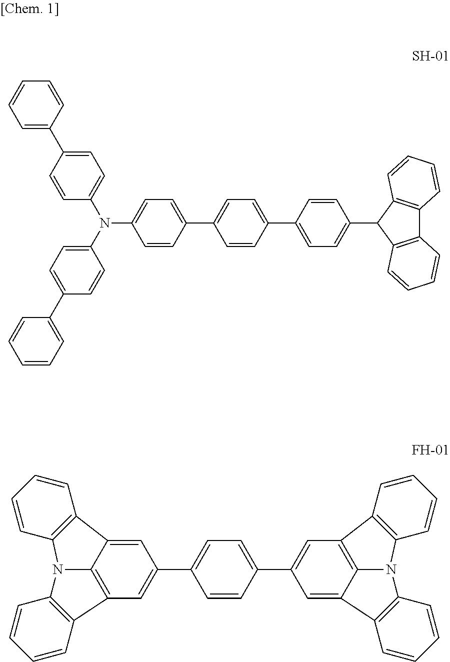 [SMILES: c1ccc(-c2ccc(N(c3ccc(-c4ccccc4)cc3)c3ccc(-c4ccc(-c5ccc(C6c7ccccc7-c7ccccc76)cc5)cc4)cc3)cc2)cc1 ; c1ccc2c(c1)c1cc(-c3ccc(-c4cc5c6ccccc6n6c7ccccc7c(c4)c56)cc3)cc3c4ccccc4n2c13]

### CITATION LIST

### Patent Literature

PTL 1 Japanese Patent Laid-Open No. 2009-298779
PTL 2 Japanese Patent Laid-Open No. 2010-087496

PTLs 1 and 2 describe compounds that can be used in organic light-emitting devices.

These compounds, however, have insufficient heat stability. In addition, organic light-emitting devices using these compounds in the hole-injecting layer, the hole-transporting layer, or the electron-blocking layer need high driving voltages.

### SUMMARY OF INVENTION

The present invention provides a novel aminoindolo[3,2,1-jk]carbazole compound having high heat stability and an organic light-emitting device having a low driving voltage and high driving durability by using the compound.

Accordingly, the present invention provides an aminoindolo[3,2,1-jk]carbazole compound represented by the following Formula [1]:

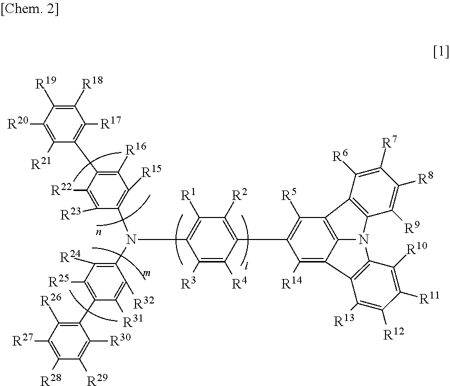

In Formula [1], l represents an integer of 1 to 3; n and m each independently represent an integer of 0 to 2; and R¹ to R³² represent hydrogen atom, alkyl groups having 1 to 8 carbon atoms or fluorine atoms, wherein the alkyl groups may contain fluorine atoms.

### Advantageous Effects of Invention

The present invention can provide a novel aminoindolo[3,2,1-jk]carbazole compound having high heat stability and an organic light-emitting device having a low driving voltage and high driving durability by using the compound.

### BRIEF DESCRIPTION OF DRAWINGS

FIG. 1 is a schematic cross-sectional view illustrating organic light-emitting devices and switching devices connected to the organic light-emitting devices.

### DESCRIPTION OF EMBODIMENT

The present invention relates to an aminoindolo[3,2,1-jk]carbazole compound represented by the following Formula [1]:

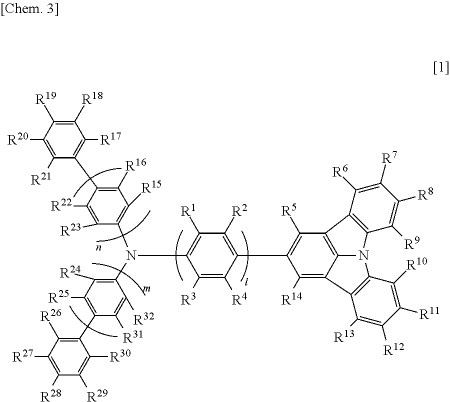

In Formula [1], l represents an integer of 1 to 3; n and m each independently represent an integer of 0 to 2; and R¹ to R³² represent hydrogen atom, alkyl groups having 1 to 8 carbon atoms or fluorine atoms, wherein the alkyl groups may contain fluorine atoms.

In Formula [1], R¹ to R³² can be hydrogen atom, alkyl groups having 1 to 6 carbon atoms or fluorine atoms.

The alkyl group may contain a fluorine atom, i.e., may be methyl fluoride or tetrafluoromethane.

Properties of the aminoindolo[3,2,1-jk]carbazole Compound According to the Present Invention

The compound according to the present invention is composed of three moieties: an aromatic amino group, an aromatic group, and an indolo[3,2,1-jk]carbazolyl group.

The presence of the aromatic amino group and the aromatic group allows the compound to have a HOMO level suitable for a hole-injecting layer, a hole-transporting layer, or an electron-blocking layer.

The aminoindolo[3,2,1-jk]carbazole compound according to the present invention includes an indolo[3,2,1-jk]carbazolyl group having higher heat stability compared with that of a carbazolyl group, which is generally used in a hole-injecting layer, a hole-transporting layer, an electron-blocking layer, or another layer. Consequently, the aminoindolo[3,2,1-jk]carbazole compound exhibits high heat stability.

The solubility in organic solvents of the aminoindolo[3,2,1-jk]carbazole compound according to the present invention increases by having an alkyl group.

Consequently, the aminoindolo[3,2,1-jk]carbazole compound having an alkyl group can easily form a film by coating.

The position of the alkyl group in the aminoindolo[3,2,1-jk]carbazole compound according to the present invention can be at least one of R¹⁸ to R²⁰ and R²⁷ to R²⁹.

The sublimability of the aminoindolo[3,2,1-jk]carbazole compound according to the present invention increases by having a substituent containing a fluorine atom.

Consequently, the aminoindolo[3,2,1-jk]carbazole compound having a substituent containing fluorine can easily form a film by deposition.

By the design described above, the aminoindolo[3,2,1-jk]carbazole compound of the present invention has high heat stability and can be applied to film formation by any of coating and deposition. In addition, it can be expected that an organic light-emitting device including the compound is driven by a low voltage.

Examples of aminoindolo[3,2,1-jk]carbazole Compound According to the Present Invention

Unlimited examples of the structural formula of the aminoindolo[3,2,1-jk]carbazole compound according to the present invention are specifically shown below.

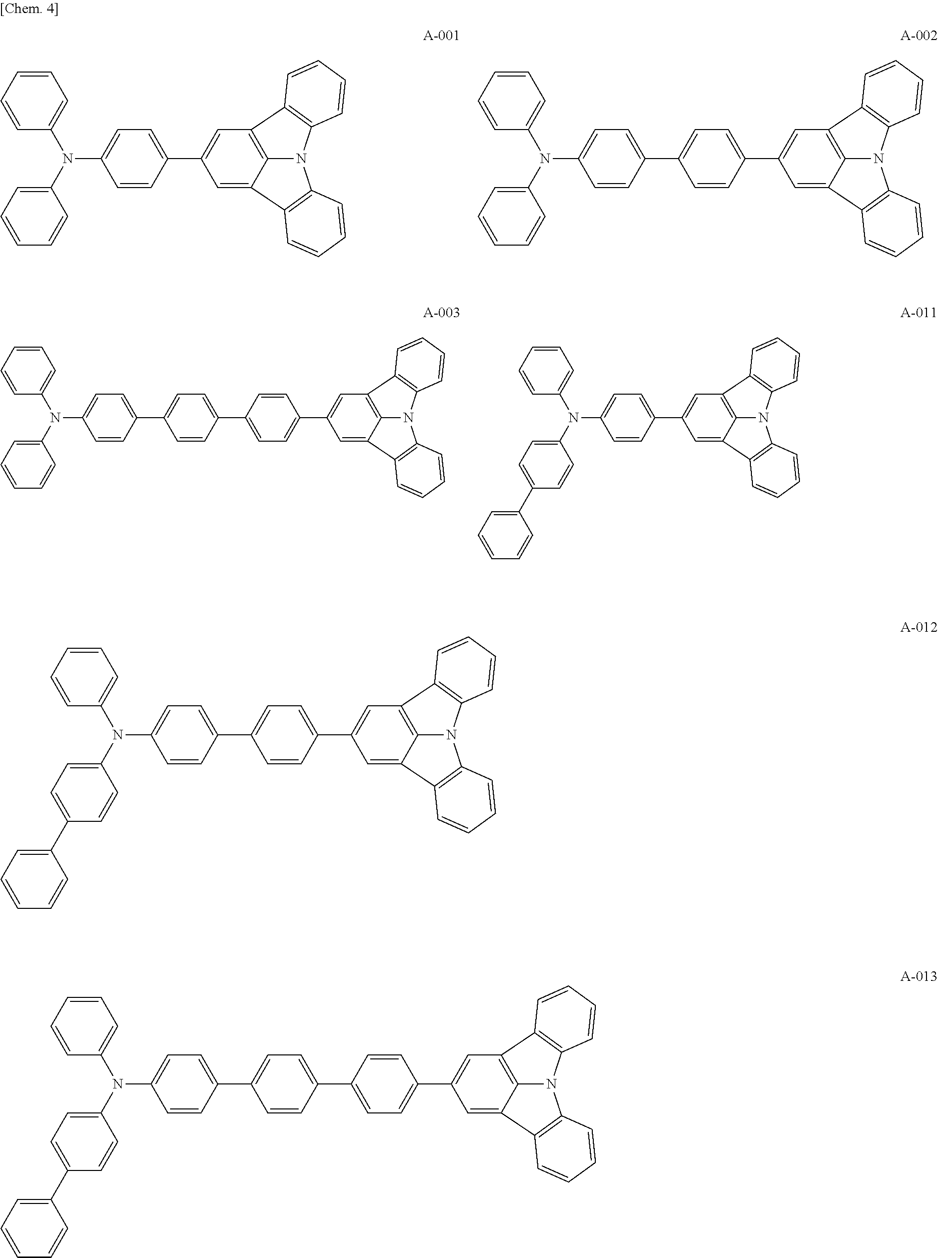 [SMILES: c1ccc(N(c2ccccc2)c2ccc(-c3cc4c5ccccc5n5c6ccccc6c(c3)c45)cc2)cc1 ; c1ccc(N(c2ccccc2)c2ccc(-c3ccc(-c4cc5c6ccccc6n6c7ccccc7c(c4)c56)cc3)cc2)cc1 ; c1ccc(N(c2ccccc2)c2ccc(-c3ccc(-c4ccc(-c5cc6c7ccccc7n7c8ccccc8c(c5)c67)cc4)cc3)cc2)cc1 ; c1ccc(-c2ccc(N(c3ccccc3)c3ccc(-c4cc5c6ccccc6n6c7ccccc7c(c4)c56)cc3)cc2)cc1 ; c1ccc(-c2ccc(N(c3ccccc3)c3ccc(-c4ccc(-c5cc6c7ccccc7n7c8ccccc8c(c5)c67)cc4)cc3)cc2)cc1 ; c1ccc(-c2ccc(N(c3ccccc3)c3ccc(-c4ccc(-c5ccc(-c6cc7c8ccccc8n8c9ccccc9c(c6)c78)cc5)cc4)cc3)cc2)cc1]

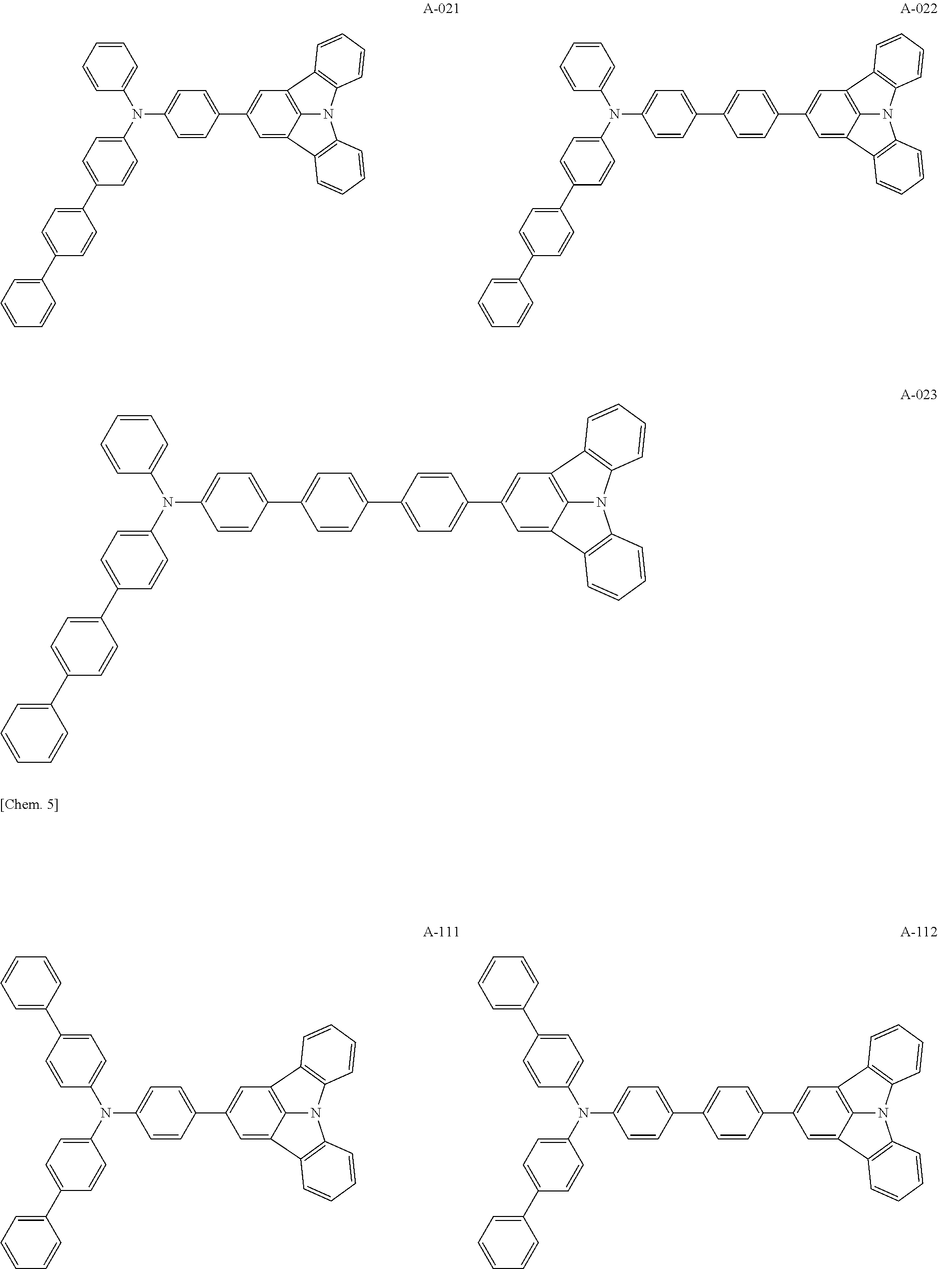 [SMILES: c1ccc(-c2ccc(-c3ccc(N(c4ccccc4)c4ccc(-c5cc6c7ccccc7n7c8ccccc8c(c5)c67)cc4)cc3)cc2)cc1 ; c1ccc(-c2ccc(-c3ccc(N(c4ccccc4)c4ccc(-c5ccc(-c6cc7c8ccccc8n8c9ccccc9c(c6)c78)cc5)cc4)cc3)cc2)cc1 ; c1ccc(-c2ccc(-c3ccc(N(c4ccccc4)c4ccc(-c5ccc(-c6ccc(-c7cc8c9ccccc9n9c%10ccccc%10c(c7)c89)cc6)cc5)cc4)cc3)cc2)cc1 ; c1ccc(-c2ccc(N(c3ccc(-c4ccccc4)cc3)c3ccc(-c4cc5c6ccccc6n6c7ccccc7c(c4)c56)cc3)cc2)cc1 ; c1ccc(-c2ccc(N(c3ccc(-c4ccccc4)cc3)c3ccc(-c4ccc(-c5cc6c7ccccc7n7c8ccccc8c(c5)c67)cc4)cc3)cc2)cc1]

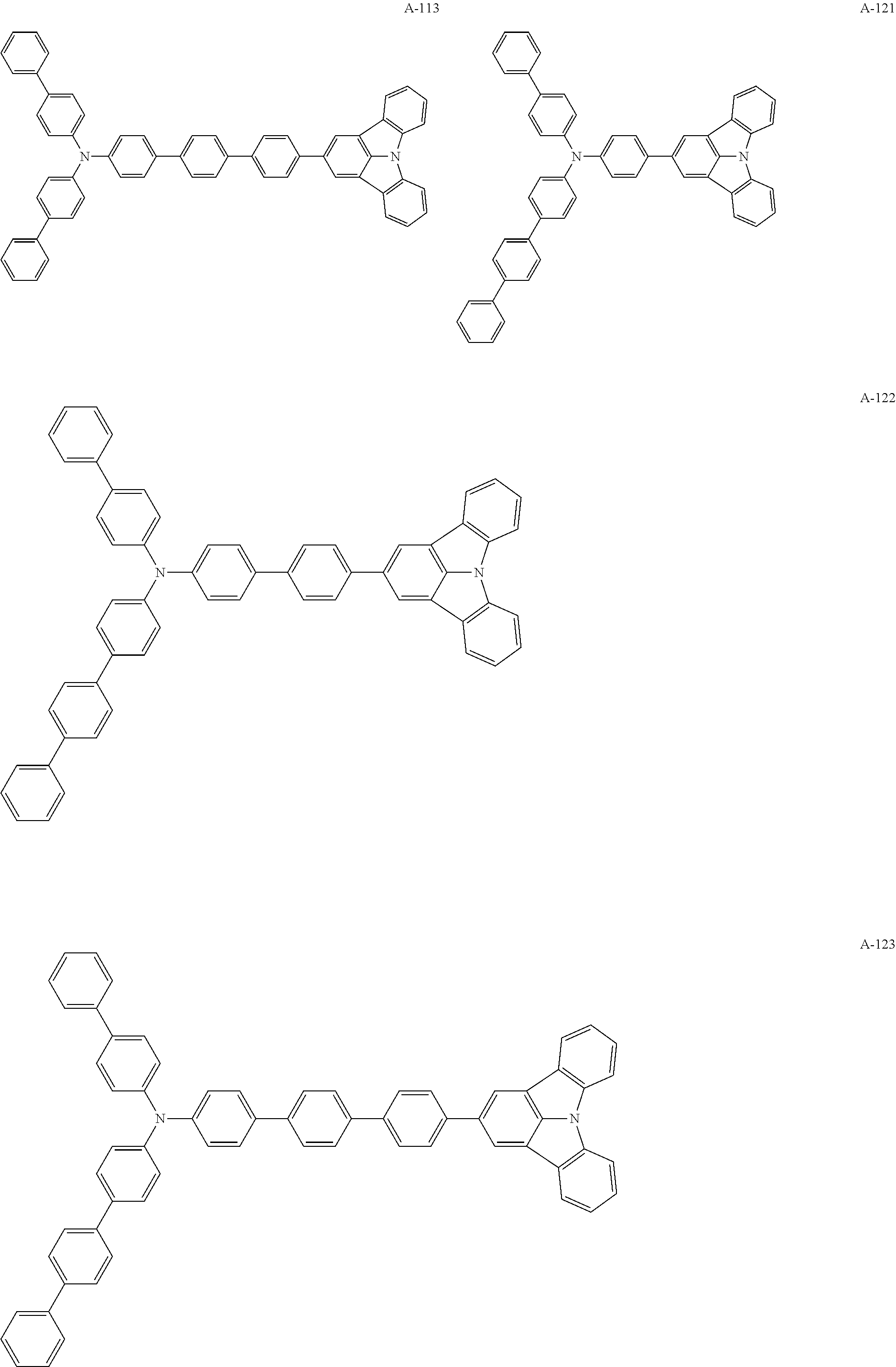 [SMILES: c1ccc(-c2ccc(N(c3ccc(-c4ccccc4)cc3)c3ccc(-c4ccc(-c5ccc(-c6cc7c8ccccc8n8c9ccccc9c(c6)c78)cc5)cc4)cc3)cc2)cc1 ; c1ccc(-c2ccc(-c3ccc(N(c4ccc(-c5ccccc5)cc4)c4ccc(-c5cc6c7ccccc7n7c8ccccc8c(c5)c67)cc4)cc3)cc2)cc1 ; c1ccc(-c2ccc(-c3ccc(N(c4ccc(-c5ccccc5)cc4)c4ccc(-c5ccc(-c6cc7c8ccccc8n8c9ccccc9c(c6)c78)cc5)cc4)cc3)cc2)cc1 ; c1ccc(-c2ccc(-c3ccc(N(c4ccc(-c5ccccc5)cc4)c4ccc(-c5ccc(-c6ccc(-c7cc8c9ccccc9n9c%10ccccc%10c(c7)c89)cc6)cc5)cc4)cc3)cc2)cc1]

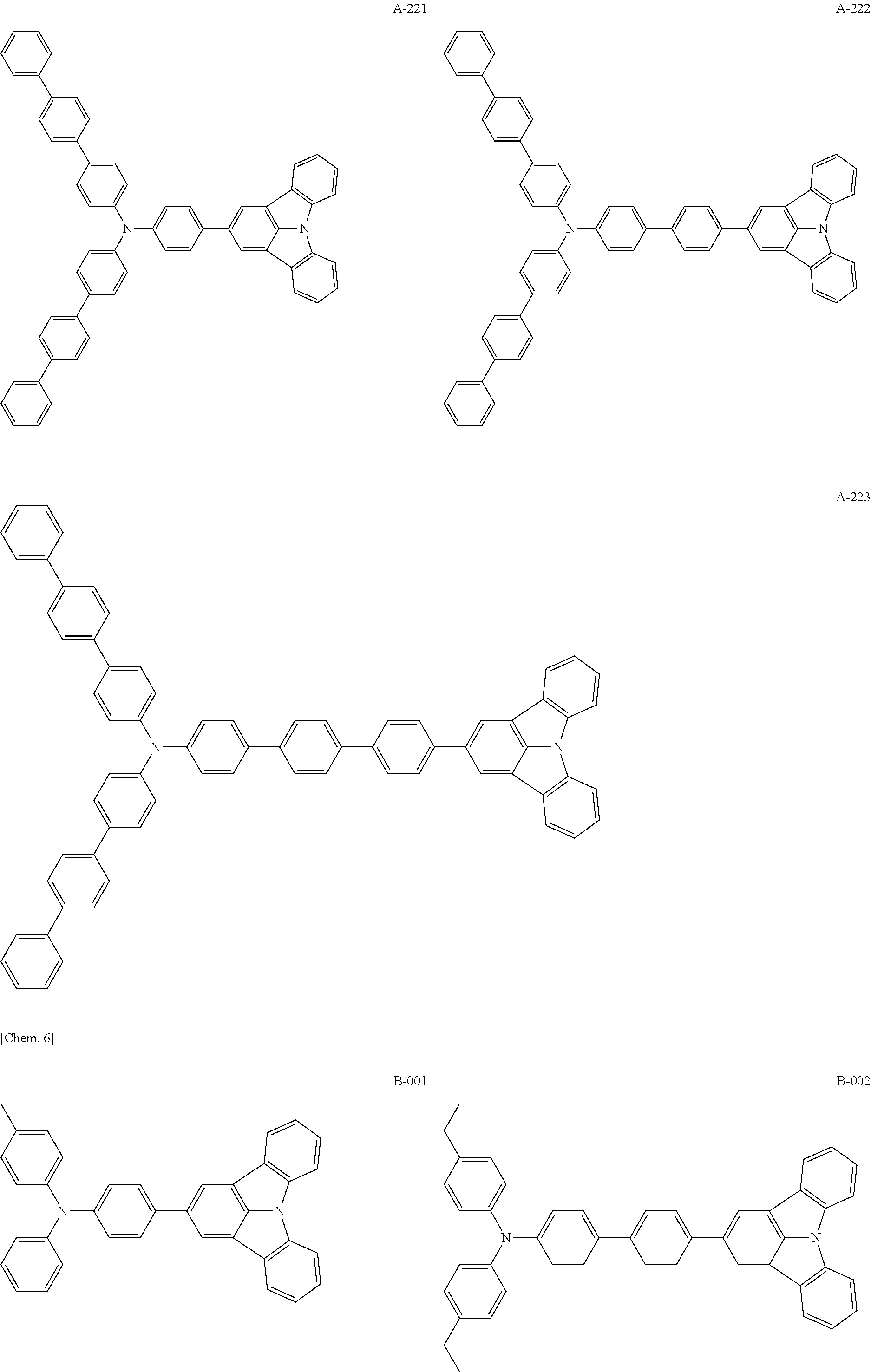

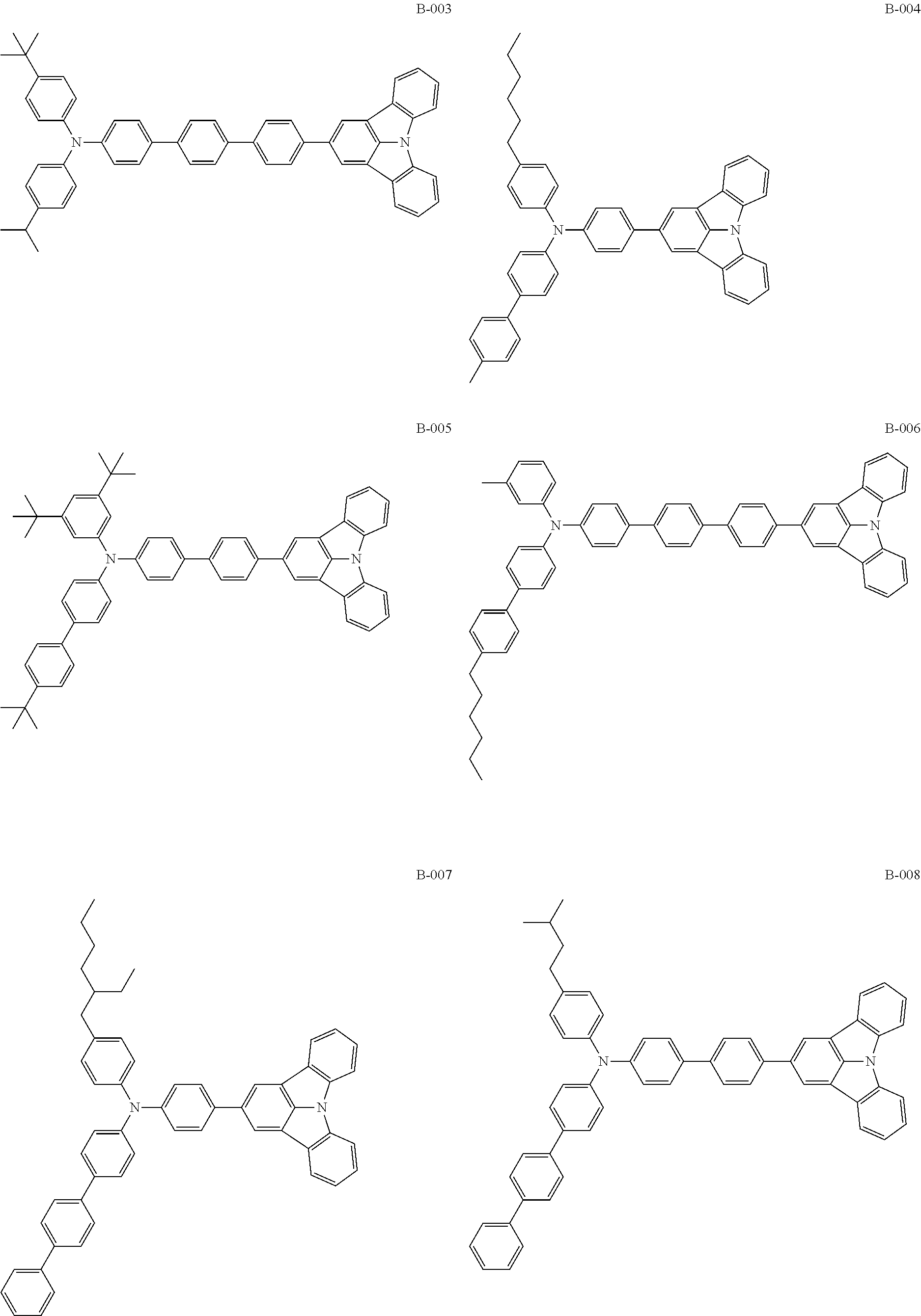

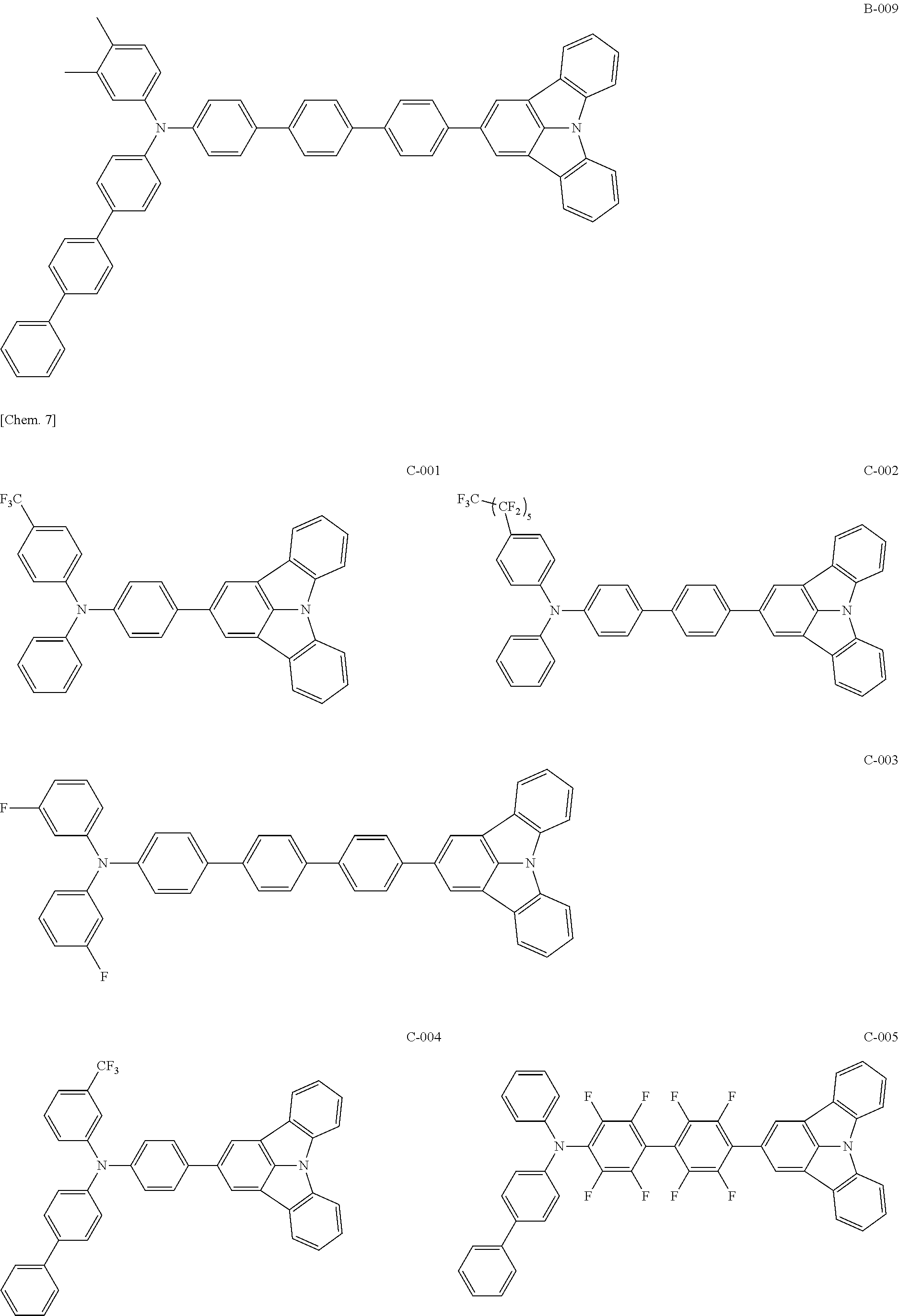

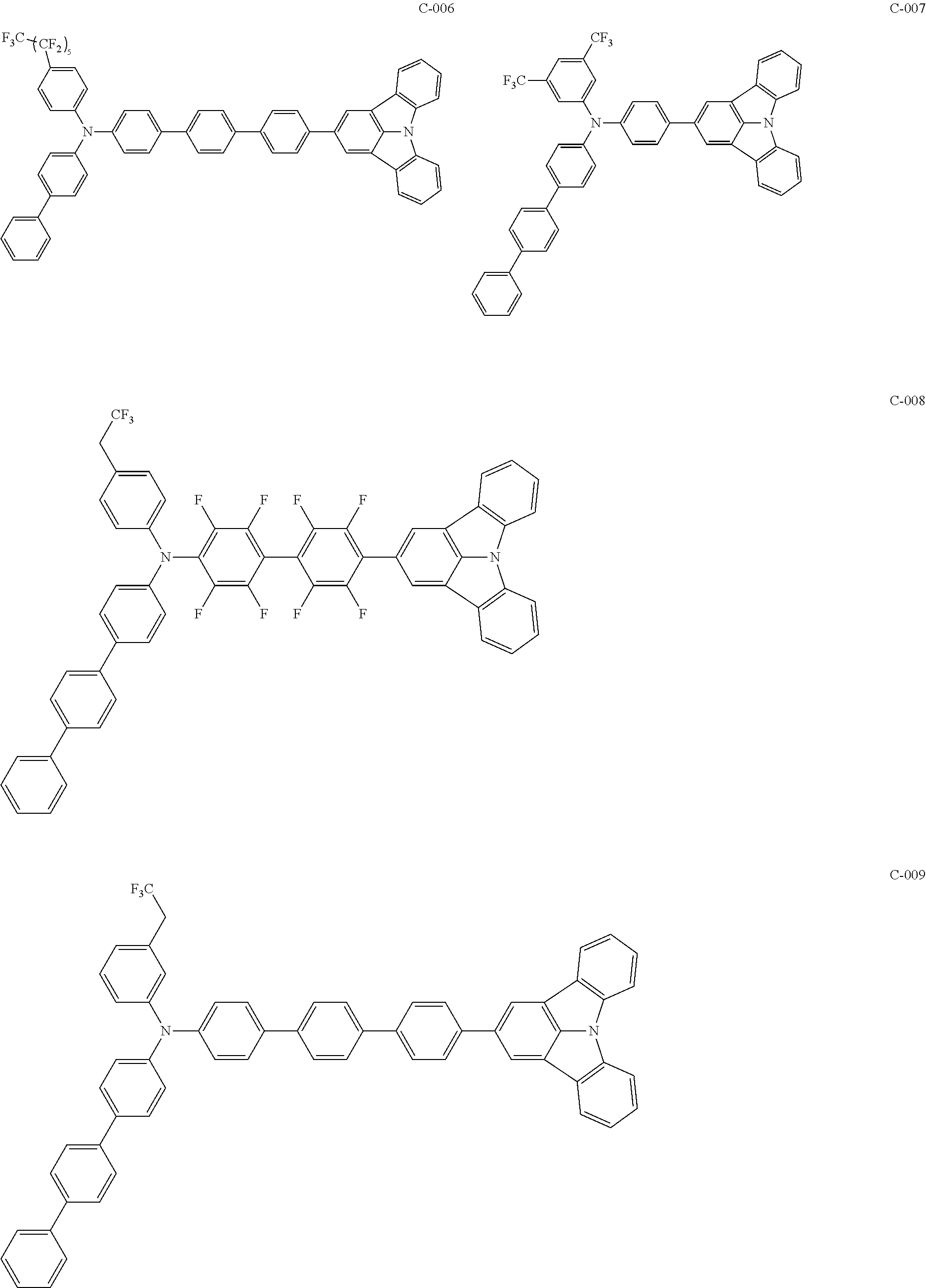

Among the exemplified compounds, the compounds belonging to group A do not contain alkyl groups and fluorine atoms.

Accordingly, these compounds in group A have high chemical stability, and an organic light-emitting device including such a compound as a hole-injecting, a hole-transporting, or an electron-blocking material can be expected to have a long lifetime.

Among the exemplified compounds, the compounds belonging to group B contain alkyl groups and thereby have high solubility and can easily form films by coating.

These compounds have shallow HOMO levels, and an organic light-emitting device including such a compound can be expected to be driven by a lower voltage. The shallow HOMO level means that the HOMO level is near the vacuum energy level.

Among the exemplified compounds, the compounds belonging to group C contain fluorine atoms, and, thereby, the intermolecular interaction between the compounds is low. As a result, the compounds have high sublimability and can further easily form films by deposition.

Example of Method of Synthesizing aminoindolo[3,2,1-jk]carbazole Compound According to the Present Invention

An example of a method of synthesizing the aminoindolo[3,2,1-jk]carbazole compound represented by Formula [1] according to the present embodiment will now be described.

The aminoindolo[3,2,1-jk]carbazole compound according to the present invention can be synthesized as shown below by coupling an aromatic amine and a bromoiodoaryl with a Pd catalyst and then coupling the coupling product and a bis(pinacol) boronic ester compound of aminoindolo[3,2,1-jk]carbazole with a Pd catalyst. This synthetic method is merely an example, and any reaction route may be used for the synthesis.

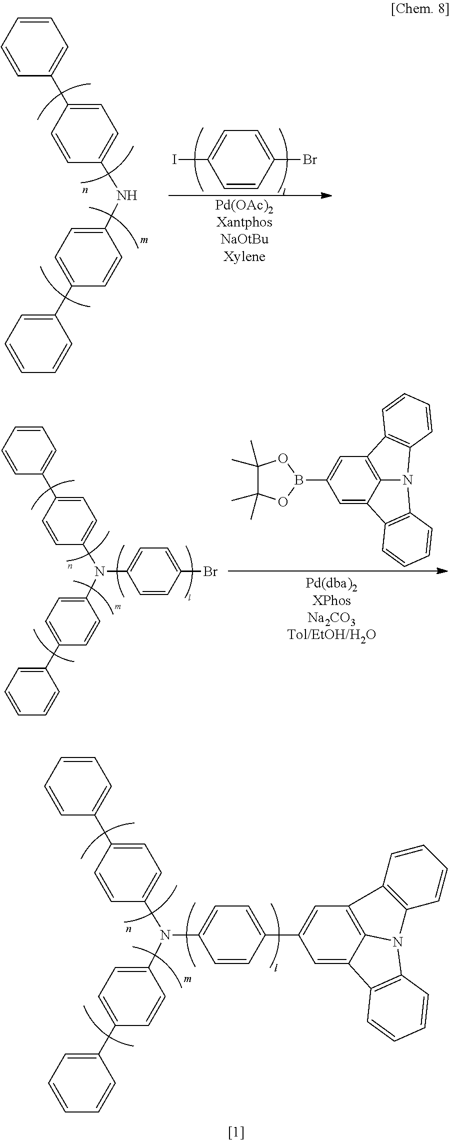

In the reaction above, a desired aminoindolo[3,2,1-jk]carbazole compound of the present invention can be synthesized by appropriately selecting n, m, and 1 and the alkyl group and the fluorine atom.

### Organic Light-Emitting Device According to the Present Embodiment

The organic light-emitting device according to the present embodiment includes at least a pair of electrodes facing each other, i.e., an anode and a cathode, and an organic compound layer disposed therebetween. In the organic light-emitting device according to the present invention, the organic compound layer includes the aminoindolo[3,2,1-jk]carbazole compound represented by Formula [1].

The organic compound layer of the organic light-emitting device according to the present embodiment may be a monolayer or a multilayer. The multilayer includes those appropriately selected from, for example, a hole-injecting layer, a hole-transporting layer, an electron-blocking layer, a light-emitting layer, a hole-blocking layer, an electron-transporting layer, an electron-injecting layer, and an exciton-diffusion-blocking layer.

A plurality of layers selected from the above-mentioned layers can be used in combination. For example, the organic light-emitting device includes a pair of electrodes, a hole-injecting layer, a hole-transporting layer, a light-emitting layer, an electron-transporting layer, and an electron-injecting layer.

The organic light-emitting device may have a plurality of light-emitting layers, and the respective devices may emit different colors of light.

The light-emitting device having a plurality of light-emitting layers may include the light-emitting layers between a pair of electrodes. For example, in one configuration, light-emitting layers respectively emitting red, green, and blue light are layered between the anode and the cathode.

The configuration of the organic light-emitting device according to the present embodiment is not limited thereto, and various layer configurations can be employed. For example, an insulating layer may be disposed at the interface between an electrode and an organic compound layer; an adhesive layer or an interference layer may be provided; or an electron-transporting layer or a hole-transporting layer may be composed of two layers having ionization potentials different from each other.

The configuration of the device may be a top emission type extracting light from the opposite side of the substrate, or a bottom emission type extracting light from the substrate side. Alternatively, a configuration in which light is extracted from both sides can also be employed.

The aminoindolo[3,2,1-jk]carbazole compound according to the present invention can be used in any layer as an organic compound layer of the organic light-emitting device and can be used, in particular, in the hole-injecting layer, the hole-transporting layer, or the electron-blocking layer.

Throughout the specification, the hole-injecting layer, the hole-transporting layer, and the electron-blocking layer are organic compound layers disposed between the anode and the light-emitting layer.

The hole-transporting layer is a layer for conducting holes injected from an electrode to the light-emitting layer. The material used for the hole-transporting layer can be a material having the HOMO level at an appropriate position.

The aminoindolo[3,2,1-jk]carbazole compound according to the present invention is an appropriate compound satisfying this requirement.

That is, the aminoindolo[3,2,1-jk]carbazole compound according to the present invention can be used in the hole-transporting layer.

In addition to the compound of the present invention, a known low-molecular or high-molecular compound may be optionally used. More specifically, for example, a hole-injecting compound, a hole-transporting compound, a host material, a light-emitting compound, an electron-injecting compound, or an electron-transporting compound can be used together. Examples of these compounds will now be described.

The hole-injecting/transporting compound can be a material possessing high hole mobility so that injection of holes from an anode is easy and that the injected holes can be transported to an light-emitting layer. Examples of the low-molecular or high-molecular material having hole-injecting/transporting ability include triarylamine derivatives, phenylenediamine derivatives, stilbene derivatives, phthalocyanine derivatives, porphyrin derivatives, poly(vinylcarbazole), poly(thiophene), and other electrically conductive polymers.

Examples of the light-emitting material mainly related to the emission function include, in addition to phosphorescent guest materials and derivatives thereof, condensation compounds (e.g., fluorene derivatives, naphthalene derivatives, pyrene derivatives, perylene derivatives, tetracene derivatives, anthracene derivatives, and rubrene), quinacridone derivatives, coumarin derivatives, stilbene derivatives, organic aluminum complexes such as tris(8-quinolinolato)aluminum, organic beryllium complexes, and polymer derivatives such as poly(phenylenevinylene) derivatives, poly(fluorene) derivatives, and poly(phenylene) derivatives.

The electron-injecting/transporting compound can be appropriately selected from those that allows easy injection of electrons from a cathode and can transport the injected electrons to a light-emitting layer, with consideration for, for example, the balance with the hole mobility of the hole-injecting/transporting compound. Examples of the material possessing the electron-injecting/transporting ability include oxadiazole derivatives, oxazole derivatives, pyrazine derivatives, triazole derivatives, triazine derivatives, quinoline derivatives, quinoxaline derivatives, phenanthroline derivatives, and organic aluminum complexes.

The material of the anode can have a work function as high as possible.

Examples of such a material include simple metals such as gold, platinum, silver, copper, nickel, palladium, cobalt, selenium, vanadium, and tungsten; alloys of these simple metals; and metal oxides such as tin oxide, zinc oxide, indium oxide, indium tin oxide (ITO), and indium zinc oxide. Electrically conductive polymers such as polyaniline, polypyrrole, and polythiophene also can be used.

These electrode materials may be used alone or in combination of two or more thereof. The anode may have either a monolayer structure or a multilayer structure.

The material of the cathode can have a low work function. Examples of such a material include alkali metals such as lithium; alkaline earth metals such as calcium; simple metals such as aluminum, titanium, manganese, silver, lead, and chromium; alloys of these simple metals such as magnesium-silver, aluminum-lithium, and aluminum-magnesium; and metal oxides such as indium tin oxide (ITO).

These electrode materials may be used alone or in combination of two or more thereof. The cathode may have either a monolayer structure or a multilayer structure.

In the organic light-emitting device according to the present embodiment, a layer containing the organic compound according to the present invention and a layer of another organic compound are formed by the following methods.

In general, a thin film is formed by vacuum deposition, ionic vapor deposition, sputtering, plasma CVD, or a known coating process using a solution of an appropriate solvent (e.g., spin coating, dipping, casting, an LB method, or an ink jet method).

A layer formed by vacuum deposition or coating of a solution hardly causes, for example, crystallization and is stable for a long time. In the case of forming a film by coating, the solution may additionally contain an appropriate binder resin.

Examples of the binder resin include, but not limited to, polyvinylcarbazole resins, polycarbonate resins, polyester resins, ABS resins, acrylic resins, polyimide resins, phenol resins, epoxy resins, silicone resins, and urea resins.

These binder resins may be singly used as a homopolymer or a copolymer or as a mixture of two or more of polymers. The solution for forming a film may further optionally contain additives such as known plasticizer, antioxidant, and ultraviolet absorber.

### Application of Organic Light-Emitting Device According to the Present Embodiment

The organic light-emitting device according to the present embodiment can be applied to a display apparatus or a lighting system. In addition, the device can be used, for example, in an exposing light source of an electrophotographic image-forming apparatus or in a backlight of a liquid crystal display apparatus.

The display apparatus has the organic light-emitting device according to the present embodiment in a display section. The display section has a plurality of pixels. Each pixel has the organic light-emitting device according to the present embodiment and a thin-film transistor (TFT) as an example of a switching device for controlling luminance. In the switching device, the drain electrode or the source electrode of the thin-film transistor is connected to the anode or the cathode of the organic light-emitting device.

The display apparatus can be used as an image display apparatus of, for example, a PC, a head mount display, or a mobile phone. The image displayed may be a two-dimensional image or a three-dimensional image.

The display apparatus may be an image output apparatus that includes an image input section for inputting image information from, for example, an area CCD, a linear CCD, or a memory card and outputs the input image to a display section.

The image output apparatus may be a digital camera having an image pickup optical system with an image pickup device, such as a CCD sensor, as the image input section.

The display apparatus may have an input function for inputting information by touching an image on the display, such as a touch panel function.

The display apparatus may be used in the display section of a multi-functional printer.

The organic light-emitting device according to the present embodiment may be used in a lighting system. This lighting system includes the organic light-emitting device according to the present embodiment and a converter circuit connected to the organic light-emitting device.

The color of illumination light of the lighting system according to the present embodiment may be white or neutral white or another color.

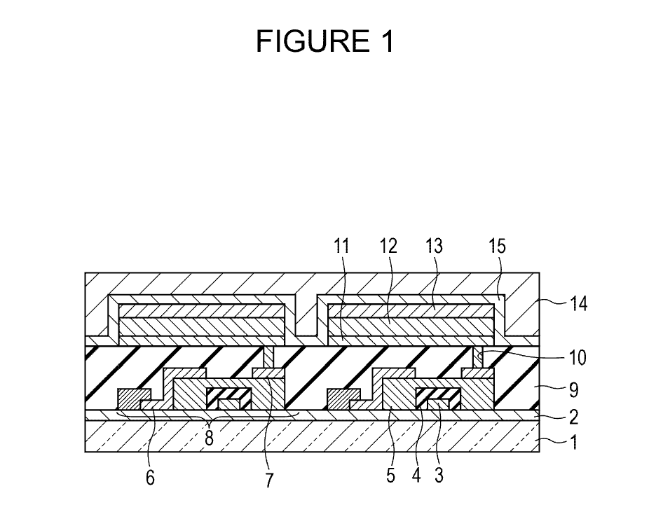

A display apparatus having the organic light-emitting device according to the present embodiment will now be described with reference to FIG. 1.

FIG. 1 is a schematic cross-sectional view illustrating organic light-emitting devices according to the present embodiment and TFTs as an example of switching devices connected to the organic light-emitting devices. This drawing shows two pairs of the organic light-emitting devices and the TFTs. The structure will now be described in detail.

The display apparatus shown in FIG. 1 includes a substrate 1 such as a glass substrate and a moisture-proof film 2 disposed on the substrate 1 for protecting TFTs or an organic compound layer. Reference numeral 3 denotes a metal gate electrode, reference numeral 4 denotes a gate insulating film, and reference numeral 5 denotes a semiconductor layer.

A thin-film transistor 8 includes a semiconductor layer 5, a drain electrode 6, and a source electrode 7. An insulating film 9 is disposed on the thin-film transistor 8. The source electrode 7 is connected to the anode 11 of the organic light-emitting device via a contact hole 10.

The display apparatus is not limited to this structure as long as either the anode or the cathode is connected to either the source electrode or the drain electrode of the thin-film transistor.

In this drawing, the organic compound layer 12 is simplified and drawn as one layer, but is actually composed of a plurality of organic compound layers. A first protection layer 14 and a second protection layer 15 are disposed on a cathode 13 for inhibiting degradation of the organic light-emitting device.

In the display apparatus according to the present embodiment, the switching device is not particularly limited and may be a transistor or an MIM element. The transistor may be a thin-film transistor employing single crystal silicon or an amorphous silicon transistor. The thin-film transistor is also called a TFT.

In the organic light-emitting device, the switching device controls the luminance. By disposing the organic light-emitting devices in a plurality of planes, images can be displayed with the respective luminance.

Alternatively, the luminance also can be controlled by producing an active matrix driver on a Si substrate and disposing the organic light-emitting devices thereon.

This is selected depending on the degree of definition. For example, in a definition for about 1-inch QVGA, the organic light-emitting devices can be disposed on a Si substrate.

Stable display with a good image quality is possible even in display for a long time by driving the display apparatus using the organic light-emitting devices according to the present embodiment.

### EXAMPLES

### Example 1

### Synthesis of Example Compound A-112

(1) Synthesis of Intermediate PCz-PB

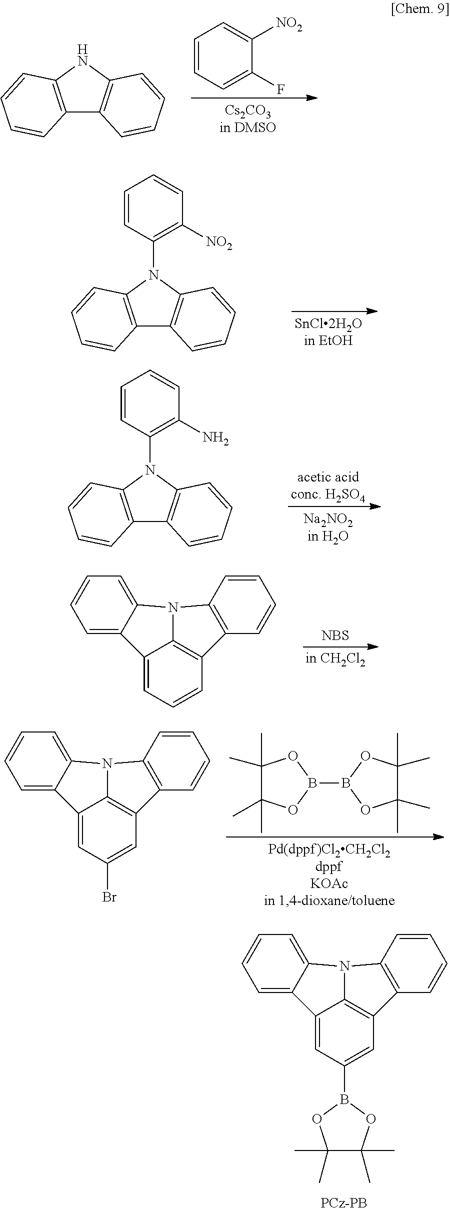

The following reagents and solvents:

9H-carbazole: 120 g (0.718 mol),

2-fluoronitrobenzene: 106 g (0.754 mol),

cesium carbonate: 152 g (1.077 mol), and

dehydrated dimethylsulfoxide: 1.8 L

were charged in a round bottom flask.

This mixture was stirred under nitrogen at room temperature for 3 days. After completion of the reaction, the mixture was poured into 3 L of ice water. The precipitated yellow solid was stirred at room temperature for 30 min and was collected by filtration. The collected solid was dissolved in 3 L of chloroform and was washed with water, dehydrated with magnesium sulfate, and concentrated to give 229 g of 9-(2-nitrophenyl)-9H-carbazole as a yellow solid.

The following reagents and a solvent:

9-(2-nitrophenyl)-9H-carbazole: 229 g (0.794 mol),

SnCl₂.2H₂O: 567 g (2.51 mol), and

ethanol: 5 L

were charged in a round bottom flask.

This mixture was stirred with heating at an internal temperature of 70° C. under nitrogen for 8 hours. After completion of the reaction, the mixture was allowed to cool and was concentrated. To the residue, 5 L of an aqueous solution of 1 N sodium hydroxide was added. The resulting suspension was stirred at room temperature for 1 hour, followed by filtration. The solid collected by filtration was dissolved in 8 L of toluene, and 7 L of an aqueous solution of 1 N sodium hydroxide was added thereto. After liquid phase separation, the aqueous layer was removed, and the organic layer was washed with water, dehydrated with magnesium sulfate, concentrated once, and heated and washed by suspension in isopropyl ether to give 124 g of 2-(9H-carbazol-9-yl)aniline as a light yellow solid (yield: 61%).

The following reagents and a solvent:

2-(9H-carbazol-9-yl)aniline: 124 g (0.480 mol),

acetic acid: 1.2 L, and

concentrated sulfuric acid: 124 mL

were charged in a round bottom flask.

This mixture was immersed in an ice water bath to cool to an internal temperature of 10° C. To the solution, a solution prepared by dissolving 33.8 g of sodium nitrite in 670 mL of distilled water was dropwise added over 15 min, followed by stirring for 10 min. Subsequently, the mixture was heated at an external temperature of 130° C. with stirring for 20 min. After completion of the reaction, the mixture was allowed to cool. One liter of distilled water was added to the mixture, and the precipitated solid was collected by filtration. This yellowish brown solid was washed by suspension in 2 L of methanol to give a brown solid. This solid was purified by column chromatography (silica gel) and then recrystallized from a solvent mixture of chloroform and ethanol to give 83.3 g of aminoindolo[3,2,1-jk]carbazole as a light-orange to white solid (yield: 72%).

The following reagents and a solvent:

aminoindolo[3,2,1-jk]carbazole: 83.3 g (0.345 mol),

N-bromosuccinimide: 67.6 g, and

dehydrated methylene chloride: 3.3 L

were charged in a round bottom flask under light shielding.

This mixture was stirred at room temperature under light shielding for 1 hour, and 250 g of silica gel was added thereto. The mixture was stirred at room temperature for 13 hours. After completion of the reaction, the silica gel was collected by filtration. The collected silica gel was washed three times with 1 L of chloroform in total. The chloroform was collected and was washed with water, dehydrated with anhydrous sodium sulfate, and concentrated. The resulting solid after concentration was recrystallized from toluene and was heated and washed with acetic acid to give 62.2 g of 2-bromoaminoindolo[3,2,1-jk]carbazole as a white solid (yield: 57%).

The resulting compound was identified by ¹H-NMR analysis.

[¹H-NMR (300 MHz, CDCl₃)]

δ 8.12 (s, 2H), 8.06-8.03 (d, 2H), 7.87-7.84 (d, 2H), 7.59-7.53 (t, 2H), 7.38-7.32 (t, 2H).

The following reagents and solvents:

2-bromoaminoindolo[3,2,1-jk]carbazole: 55.0 g (0.172 mol),

bis(pinacolato)diboron: 52.4 g (0.206 mol),

[1,1′-bis(diphenylphosphino)ferrocene]palladium(II) dichloride dichloromethane adduct: 2.11 g (2.58 mmol),

1,1′-bis(diphenylphosphino)ferrocene: 1.43 g (2.58 mmol),

potassium acetate: 42.2 g (0.430 mol),

dehydrated 1,4-dioxane: 550 mL, and

dehydrated toluene: 550 mL

were charged in a round bottom flask under light shielding.

This mixture was deaerated and was then heated at an external temperature of 120° C. with stirring under argon for 17 hours. After completion of the reaction, the mixture was allowed to cool and was concentrated. The resulting solid after concentration was heated and washed by suspension in toluene, followed by purification by column chromatography (silica gel) to give a white solid. This solid was washed with hexane and isopropyl ether to give 48 g of PCz-PB as a white solid (yield: 76%).

The resulting compound was identified by ¹H-NMR analysis.

[¹H-NMR (300 MHz, CDCl₃)]

δ 8.57 (s, 2H), 8.15-8.13 (d, 2H), 7.93-7.90 (d, 2H), 7.59-7.53 (t, 2H), 7.39-7.34 (t, 2H), 1.45 (s, 12H).

(2) Synthesis of Example Compound A-112

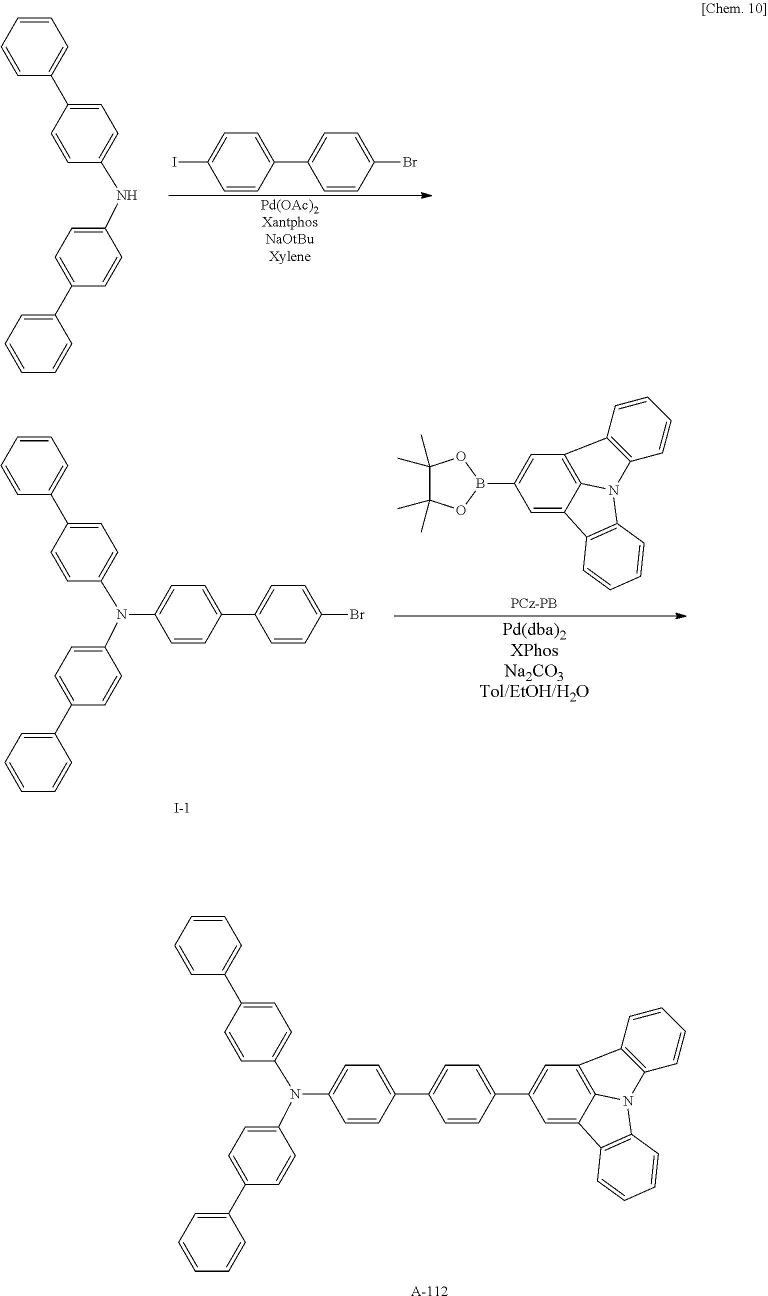

The following reagents and solvents:

bis([1,1′-biphenyl]-4-yl)amine: 0.985 g (3.06 mmol),

4-bromo-4′-iodo-1,1′-biphenyl: 1.0 g (2.79 mmol),

palladium acetate: 16 mg (0.07 mmol),

xantphos: 81 mg (0.14 mmol),

sodium tertiary butoxide: 402 mg (4.18 mmol), and

xylene: 10 mL

were charged in a round bottom flask.

This mixture was heated at an external temperature of 120° C. with stirring under nitrogen for 2 hours. After completion of the reaction, the solution was allowed to cool, and 30 mL of methanol was added thereto. The resulting solution was washed with methanol and subjected to purification by suction filtration and column chromatography (silica gel, toluene/heptane=1/2) to give 1.052 g of white powder I-1 (yield: 68%).

The following reagents and solvents:

PCz-PB: 455 mg (1.24 mmol),

I-1: 690 mg (1.24 mmol),

tetrakis(triphenylphosphine)palladium(0): 28 mg (0.024 mmol),

sodium carbonate: 263 mg (2.48 mmol),

toluene: 40 mL,

ethanol: 20 mL, and

water: 20 mL

were charged in a round bottom flask.

This mixture was heated at an external temperature of 100° C. with stirring for 5 hours. After completion of the reaction, the mixture was allowed to cool, washed with methanol, and subjected to suction filtration. The resulting product was dissolved in toluene under heating, subjected to hot filtration through silica gel, and recrystallized to give a white powder. The resulting powder was dried in vacuum at 130° C. and was purified by sublimation under conditions of 1×10⁻⁴ Pa and 380° C. to give 135 mg of Example Compound A-112 with high purity (yield: 15%).

The results of identification of the resulting compound are shown below:

### [MALDI-TOF-MS]

Observed value: m/z=712.405, calculated value: C₅₄H₃₆N₂=712.29,

[¹H-NMR (400 MHz, CDCl₃)]

δ 8.31 (s, 2H), 8.20-8.18 (d, 2H), 7.95-7.93 (d, 2H), 7.86-7.84 (d, 2H), 7.77-7.75 (d, 2H), 7.65-7.54 (m, 12H), 7.46-7.26 (m, 14H).

The glass transition temperature (hereinafter, referred to as Tg) of Example Compound A-112 measured with an ultra-high sensitive differential scanning calorimeter, DSC 204 F1 Phoenix (registered trademark), was 145° C.

### Example 2

### Synthesis of Example Compound A-022

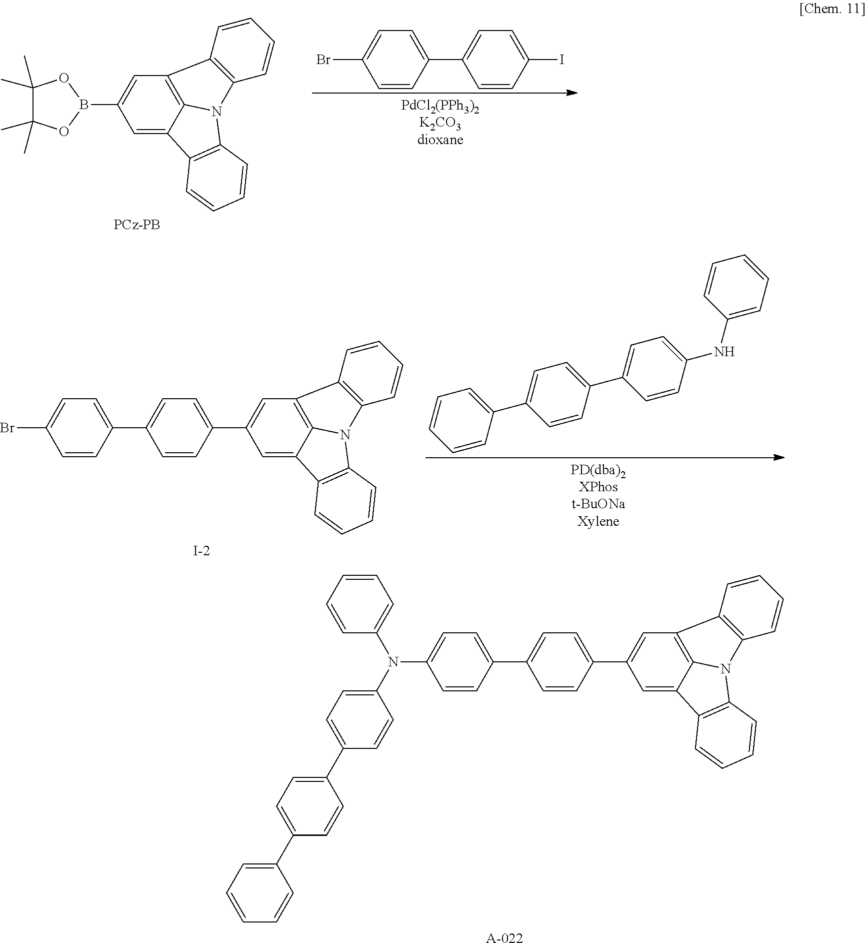

The following reagents and solvents:

PCz-PB: 3.67 g (10 mmol),

4-bromo-4′-iodo-1,1′-biphenyl: 3.59 g (10 mmol),

dichlorobis(triphenylphosphine)palladium: 280 mg (0.4 mmol),

potassium carbonate: 2.07 g (15 mmol), dioxane: 80 mL, and

water: 5 mL

were charged in a round bottom flask.

This mixture was heated at an external temperature of 100° C. with stirring under nitrogen for 9 hours. After completion of the reaction, the mixture was allowed to cool, and 200 mL of chlorobenzene was added thereto. After dissolving by heating, hot filtration through silica gel, recrystallization, and concentration were performed. The resulting product was recrystallized from 100 mL of toluene and dried in vacuum at 130° C. to give 2.3 g of 1-2 (yield: 48.6%).

The following reagents and solvents:

N-phenyl-[1,1′:4′,1″-terphenyl]-4-amine: 1.05 g (3.30 mmol),

I-2: 1.54 g (3.26 mmol),

bis(dibenzylideneacetone)palladium(0): 94 mg (0.163 mmol),

XPhos: 155 mg (0.325 mmol),

sodium tertiary butoxide: 626 mg (6.51 mmol), and

xylene: 100 mL

were charged in a round bottom flask.

This mixture was heated at an external temperature of 120° C. with stirring under nitrogen for 3 hours. After completion of the reaction, the resulting product was dissolved in toluene under heating, subjected to hot filtration through silica gel, and recrystallized to give a white powder. The resulting powder was dried in vacuum at 130° C. and was purified by sublimation under conditions of 3.3×10⁻³ Pa and 380° C. to give 230 mg of Example Compound A-022 with high purity.

The results of identification of the resulting compound are shown below:

### [MALDI-TOF-MS]

Observed value: m/z=712.484, calculated value: C₅₄H₃₆N₂=712.29

[¹H-NMR (400 MHz, CDCl₃)]

δ 8.31 (s, 2H), 8.21-8.19 (d, 2H), 7.96-7.94 (d, 2H), 7.86-7.84 (d, 2H), 7.76-7.74 (d, 2H), 7.68-7.56 (m, 12H), 7.49-7.31 (m, 8H), 7.25-7.22 (m, 5H), 7.11-7.07 (t, 1H).

The glass transition temperature (hereinafter, referred to as Tg) of Example Compound A-022 measured with an ultra-high sensitive differential scanning calorimeter, DSC 204 F1 Phoenix (registered trademark), was 143° C.

### Example 3

### Synthesis of Example Compound A-113

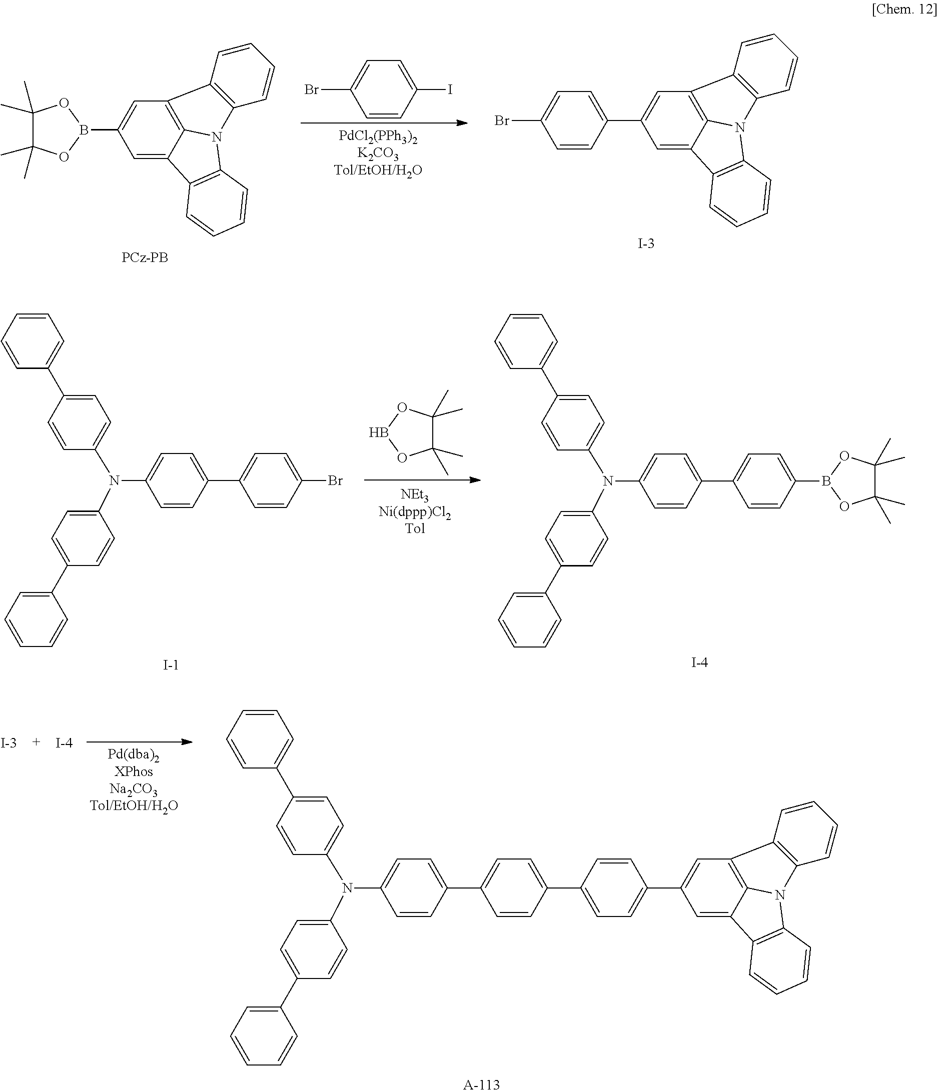

(1) Synthesis of intermediate I-3

The following reagents and solvents:

PCz-PB: 5 g (13.6 mmol),

4-bromo-4′-iodo-1,1′-biphenyl: 3.85 g (12.5 mmol),

dichlorobis(triphenylphosphine)palladium: 478 mg (0.68 mmol),

potassium carbonate: 5.64 g (40.8 mmol),

toluene: 100 mL,

ethanol: 50 mL, and

water: 50 mL

were charged in a round bottom flask.

This mixture was heated at an external temperature of 100° C. with stirring under nitrogen for 3 hours. After completion of the reaction, the mixture was allowed to cool, and toluene was added thereto to extract the resulting product, followed by concentration. The resulting product was purified by column chromatography (silica gel, chloroform/heptane=1/2), concentrated, and dried in vacuum at 130° C. to give 2 g of 1-3 (yield: 40.4%).

(2) Synthesis of Intermediate I-4

The following reagent and solvent:

I-1: 1.4 g (2.53 mmol), and

toluene: 50 mL

were charged in a round bottom flask.

This mixture was subjected to nitrogen bubbling, and the following reagents:

triethylamine: 2.65 mL (20.2 mmol),

[1,3-bis(diphenylphosphino)propane]nickel(II) dichloride: 274 mg (0.50 mmol), and

4,4,5,5-tetramethyl-1,3,2-dioxaborolane: 1.84 mL (12.68 mmol)

were further added to the round bottom flask.

This mixture was heated at an external temperature of 100° C. with stirring under nitrogen for 6 hours. After completion of the reaction, the mixture was allowed to cool, and toluene was added thereto to extract the resulting product, followed by concentration. The resulting product was purified by column chromatography (silica gel, toluene/heptane=1/2), concentrated, and washed with methanol. After filtration, drying in vacuum at 130° C. was performed to give 1.22 g of 1-4 (yield: 80.4%).

(3) Synthesis of Example Compound A-113

The following reagents and solvents:

I-3: 792 mg (2 mmol),

I-4: 1.2 g (2 mmol),

bis(dibenzylideneacetone)palladium(0): 23 mg (0.04 mmol),

XPhos: 38 mg (0.08 mmol),

sodium carbonate: 636 mg (6 mmol),

toluene: 50 mL,

ethanol: 20 mL, and

water: 20 mL

were charged in a round bottom flask.

This mixture was heated at an external temperature of 90° C. with stirring under nitrogen for 3 hours. After completion of the reaction, water and ethanol were added to the mixture, followed by suction filtration. The resulting product was purified by column chromatography (silica gel, chlorobenzene/methylcyclohexane=1/2), concentrated, and washed with ethanol, followed by suction filtration. The resulting powder was dried in vacuum at 110° C. and was then purified by sublimation under conditions of 4.1×10⁻⁴ Pa and 395° C. to give 418 mg of Example Compound A-113 with high purity (yield: 26.4%).

The results of identification of the resulting compound are shown below:

### [MALDI-TOF-MS]

Observed value: m/z=788.734, calculated value: C₆₀H₄₀N₂=788.32

[¹H-NMR (400 MHz, CDCl₃)]

δ 8.32 (s, 2H), 8.21-8.19 (d, 2H), 7.96-7.94 (d, 2H), 7.89-7.87 (d, 2H), 7.82-7.78 (m, 4H), 7.74-7.71 (d, 2H), 7.62-7.54 (m, 13H), 7.46-7.26 (m, 13H).

The glass transition temperature (hereinafter, referred to as Tg) of Example Compound A-113 measured with an ultra-high sensitive differential scanning calorimeter, DSC 204 F1 Phoenix (registered trademark), was 157° C.

### Comparative Example 1

### Comparison of Glass Transition Temperature Tg

The glass transition temperatures (hereinafter, referred to as Tg) of comparative compound SH-01 and comparative compound SH-02 shown below were measured by DSC 204 F1 Phoenix (registered trademark) and were 141° C. and 125° C., respectively. Table 1 shows comparison with Examples of the present invention.

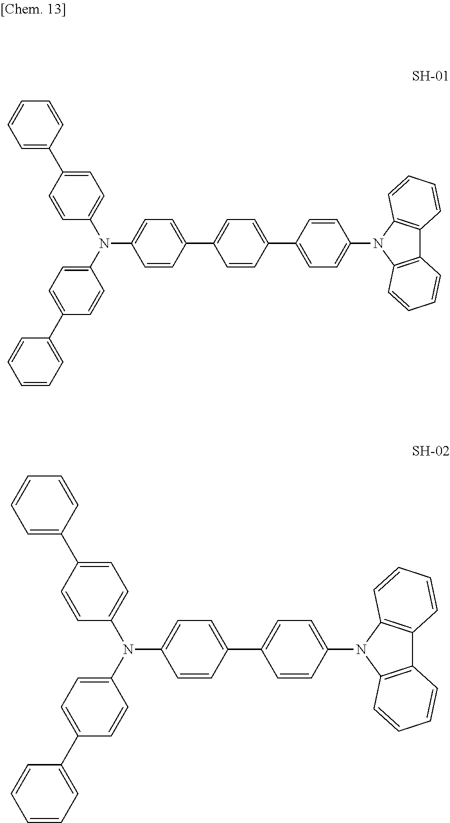 [SMILES: c1ccc(-c2ccc(N(c3ccc(-c4ccccc4)cc3)c3ccc(-c4ccc(-c5ccc(-n6c7ccccc7c7ccccc76)cc5)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

TABLE 1

| | Glass transition temperature Tg/° C. |
|---|---|
| Example compound A-112 | 145 |
| Comparative compound SH-02 | 125 |
| Example compound A-113 | 157 |
| Comparative compound SH-01 | 141 |

The Tg of each of comparative compounds SH-01 and SH-02 is increased by 16 to 20° C. by replacing the carbazolyl group with an indolo[3,2,1-jk]carbazolyl group. It is thus recognized that the heat stability of the Example compounds is higher than that of the comparative compounds.

### Example 4

In this example, a bottom emission type organic light-emitting device having a configuration composed of anode/hole-transporting layer/light-emitting layer/hole-blocking layer/electron-transporting layer/electron-injecting layer/cathode disposed in this order on a substrate was produced by the following method.

A film of indium tin oxide (ITO) was formed on a glass substrate by sputtering as an anode having a thickness of 120 nm. The glass substrate provided with the ITO film was subjected to ultrasonic washing in acetone and isopropyl alcohol (IPA) in this order, washed by boiling in IPA, and then dried. Furthermore, the substrate was subjected to UV/ozone washing. The thus-treated glass substrate was used as a transparent electrically conductive support substrate (ITO substrate). On this ITO substrate, organic compound layers and electrode layers shown below were successively formed by resistance heating vacuum vapor deposition in a vacuum chamber. The layers were:

hole-transporting layer (25 nm) A-112,

light-emitting layer (20 nm), host material: H-1, guest material: D-1 (1 wt %),

hole-blocking layer (10 nm) HBM-1,

electron-transporting layer (20 nm) ETM-1,

electron-injecting layer (0.5 nm) lithium fluoride, and

metal electrode layer (100 nm) aluminum.

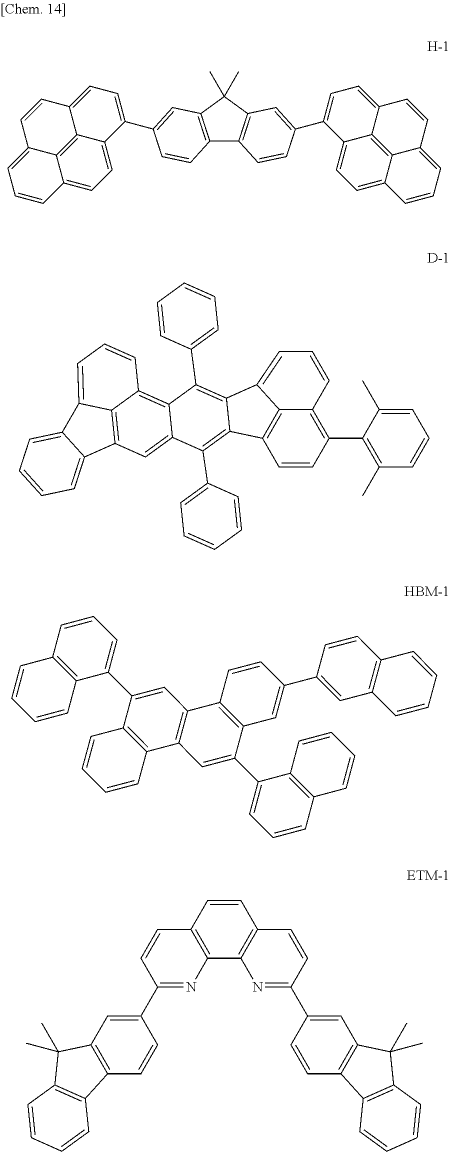

Then, in order to prevent deterioration of the organic light-emitting device due to absorption of moisture, covering with a protective glass plate and sealing with an acrylic polymer adhesive were performed in a dried air atmosphere. Thus, an organic light-emitting device was produced.

A voltage was applied between a positive ITO electrode and a negative Al electrode of the resulting organic light-emitting device. As a result, a blue light emission was observed. As for characteristics of the organic light-emitting device, the current-voltage characteristics were measured with an ammeter 2700 manufactured by Keithley Instruments, Inc., and the luminance was measured with BM7-fast manufactured by Topcon Corp.

H-1, D-1, HBM-1, and ETM-1 used in Example 4 were synthesized with reference to U.S. Patent Publication No. 2005/0236977, Japanese Patent Laid-Open No. 2010-270103, International Publication No. WO2010/107037, and International Publication No. WO2009/139501, respectively.

### Example 5

An organic light-emitting device was produced as in Example 4 except that the hole-transporting layer was formed using A-022 instead of A-112. A voltage was applied between a positive ITO electrode and a negative Al electrode of the resulting organic light-emitting device. As a result, a blue light emission was observed.

### Example 6

An organic light-emitting device was produced as in Example 4 except that the hole-transporting layer was formed using A-113 instead of A-112. A voltage was applied between a positive ITO electrode and a negative Al electrode of the resulting organic light-emitting device. As a result, a blue light emission was observed.

### Comparative Example 2

An organic light-emitting device was produced as in Example 4 except that the hole-transporting layer was formed using SH-01 instead of A-112. A voltage was applied between a positive ITO electrode and a negative Al electrode of the resulting organic light-emitting device. As a result, a blue light emission was observed.

Regarding the organic light-emitting devices in Examples 4 to 6 and Comparative Example 2, Table 2 shows the relative voltage at 6000 cd/m² (when the voltage in the organic light-emitting device of Comparative Example 2 was defined as 1) and the relative time for reducing brightness by 4% in driving at a constant current of 25 mA/m² (when the time in the organic light-emitting device of Comparative Example 2 was defined as 1).

TABLE 2

| | | | Relative time for |
|---|---|---|---|
| | | Relative | reducing brightness by |
| | | voltage (V) | 4% in driving at a constant |
| | Compound | at 6000 cd/m² | current of 25 mA/m² |
| Example 4 | A-112 | 0.968 | 1 |
| Example 5 | A-022 | 0.966 | 1.31 |
| Example 6 | A-113 | 0.957 | 1.58 |
| Comparative | SH-01 | 1 | 1 |
| Example 2 | | | |

The Example compounds allowed a reduction in driving voltage and an increase in endurance time of driving compared with those by the comparative compound.

As described above, the aminoindolo[3,2,1-jk]carbazole compound according to the present invention has satisfactory heat stability, and a light-emitting device in which the compound is used can have a low driving voltage and high driving durability.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-168335, filed Aug. 1, 2011, which is hereby incorporated by reference herein in its entirety.

1. An aminoindolo[3,2,1-jk]carbazole compound represented by the following Formula [1]: 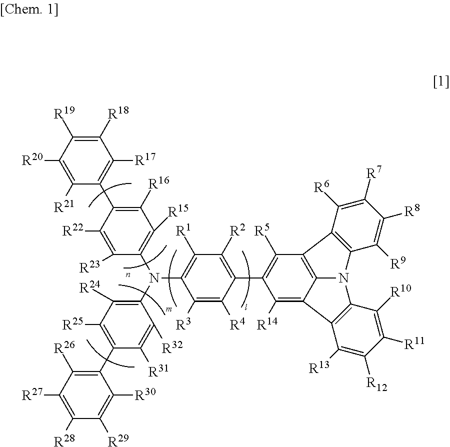
in Formula [1], l represents an integer of 1 to 3; n and m each independently represent an integer of 0 to 2; and R¹ to R³² represent hydrogen atom, alkyl groups having 1 to 8 carbon atoms or fluorine atoms, wherein the alkyl groups optionally contain fluorine atoms.

2. An organic light-emitting device comprising a pair of electrodes and an organic compound layer disposed between the pair of electrodes, wherein
the organic compound layer includes the aminoindolo[3,2,1-jk]carbazole compound according to claim 1.

3. The organic light-emitting device according to claim 2, wherein the organic compound layer is a hole-injecting layer, a hole-transporting layer, or an electron-blocking layer.

4. A display apparatus comprising a plurality of pixels each having an organic light-emitting device according to claim 2 and a switching device connected to the organic light-emitting device.

5. An image input apparatus comprising a display section for displaying an image and an input section for inputting image information, wherein the display section includes a plurality of pixels each having an organic light-emitting device according to claim 2 and a switching device connected to the organic light-emitting device.

6. A lighting system comprising an organic light-emitting device according to claim 2 and a converter circuit connected to the organic light-emitting device.

7. A display apparatus comprising a plurality of pixels each having an organic light-emitting device according to claim 3 and a switching device connected to the organic light-emitting device.

8. An image input apparatus comprising a display section for displaying an image and an input section for inputting image information, wherein the display section includes a plurality of pixels each having an organic light-emitting device according to claim 3 and a switching device connected to the organic light-emitting device.

9. A lighting system comprising an organic light-emitting device according to claim 3 and a converter circuit connected to the organic light-emitting device.
